(19) United States
(12) Patent Application Publication
(10) Pub. No.: US 2025/0079201 A1
(43) Pub. Date: Mar. 6, 2025

(54) HEAT TREATMENT APPARATUS FOR HEATING SUBSTRATE BY LIGHT IRRADIATION

(71) Applicant: SCREEN Holdings Co., Ltd., Kyoto (JP)

(72) Inventors: Takahiro YAMADA, Kyoto-shi (JP); Shogo SHIGEMASU, Kyoto-shi (JP); Nobuo EDAMOTO, Kyoto-shi (JP)

(21) Appl. No.: 18/757,377

(22) Filed: Jun. 27, 2024

(30) Foreign Application Priority Data
Aug. 30, 2023 (JP) 2023-139795

(51) Int. Cl. H01L 21/67; B23K 26/064; B23K 101/40; H01S 5/42

(52) U.S. Cl. CPC H01L 21/67115; B23K 26/064; H01S 5/423; B23K 2101/40

(57) ABSTRACT

A flash heating part including a plurality of flash lamps is provided over a chamber for receiving a semiconductor wafer therein, and an auxiliary heating part including a plurality of laser diodes and a plurality of VCSELs (Vertical Cavity Surface Emitting Lasers) is provided under the chamber. During the preheating of the semiconductor wafer, an optical element irradiates the entire surface of the semiconductor wafer with light emitted from the laser diodes with a uniform illuminance distribution while the VCSELs irradiate a peripheral portion of the semiconductor wafer with highly directional light. The laser diodes, which irradiate the semiconductor wafer with relatively intense light with a wavelength shorter than 1 μm, are capable of heating the semiconductor wafer efficiently to a high temperature. The light irradiation from the VCSELs provides a uniform in-plane temperature distribution of the semiconductor wafer.

### BACKGROUND OF THE INVENTION

### Field of the Invention

The present invention relates to a heat treatment apparatus which irradiates a substrate with light to heat the substrate. Examples of the substrate to be treated include a semiconductor wafer, a substrate for a liquid crystal display device, a substrate for a flat panel display (FPD), a substrate for an optical disk, a substrate for a magnetic disk, and a substrate for a solar cell.

### Description of the Background Art

In the process of manufacturing a semiconductor device, attention has been given to flash lamp annealing (FLA) which heats a semiconductor wafer in an extremely short time. The flash lamp annealing is a heat treatment technique in which xenon flash lamps (the term “flash lamp” as used hereinafter refers to a “xenon flash lamp”) are used to irradiate a surface of a semiconductor wafer with a flash of light, thereby raising the temperature of only the surface of the semiconductor wafer in an extremely short time (several milliseconds or less).

The xenon flash lamps have a spectral distribution of radiation ranging from ultraviolet to near-infrared regions. The wavelength of light emitted from the xenon flash lamps is shorter than that of light emitted from conventional halogen lamps, and approximately coincides with a fundamental absorption band of a silicon semiconductor wafer. Thus, when a semiconductor wafer is irradiated with a flash of light emitted from the xenon flash lamps, the temperature of the semiconductor wafer can be raised rapidly, with only a small amount of light transmitted through the semiconductor wafer. Also, it has turned out that flash irradiation, that is, the irradiation of a semiconductor wafer with a flash of light in an extremely short time of several milliseconds or less allows a selective temperature rise only near the surface of the semiconductor wafer.

Such flash lamp annealing is used for processes that require heating in an extremely short time, e.g. typically for the activation of impurities implanted in a semiconductor wafer. The irradiation of the surface of the semiconductor wafer implanted with impurities by an ion implantation process with a flash of light emitted from the flash lamps allows the temperature rise in the surface of the semiconductor wafer to an activation temperature only for an extremely short time, thereby achieving only the activation of the impurities without deep diffusion of the impurities.

A typical example of apparatuses for performing such flash lamp annealing includes a heat treatment apparatus in which flash lamps are provided over a chamber that receives a semiconductor wafer therein and halogen lamps are provided under the chamber (as disclosed, for example, in U.S. Patent Application Publication No. 2011/0262115). In the apparatus disclosed in U.S. Patent Application Publication No. 2011/0262115, a semiconductor wafer is preheated by light irradiation from the halogen lamps, and thereafter a front surface of the semiconductor wafer is irradiated with flashes of light from the flash lamps. The preheating is performed by the halogen lamps because only the flash irradiation makes it difficult for the front surface of the semiconductor wafer to reach a target temperature.

The halogen lamps mainly emit infrared light with a relatively long wavelength. Semiconductor wafers of silicon have a low spectral absorptance of infrared light with a longer wavelength of not less than 1 μm in a low temperature range of 500° C. or below. In other words, semiconductor wafers at 500° C. or below do not absorb much infrared light emitted from the halogen lamps. This results in inefficient heating of the semiconductor wafers in the initial stage of the preheating.

To solve such a problem, U.S. Patent Application Publication No. 2022/0214109 proposes the use of LED (Light Emitting Diode) lamps in place of the halogen lamps for the preheating of a semiconductor wafer. LED lamps which emit light with a wavelength of not greater than 1 μm are capable of efficiently heating even a relatively low-temperature semiconductor wafer.

However, because of the relatively low outputs of the LED lamps, it has been sometimes difficult for the LED lamps to raise the temperature of semiconductor wafers to a required preheating temperature. The installation of a large number of LED lamps is required to raise the temperature of the semiconductor wafers to a predetermined preheating temperature with the use of the LED lamps. This results in increases in costs and installation space.

### SUMMARY

The present invention is intended for a heat treatment apparatus for irradiating a substrate with light to heat the substrate.

According to one aspect of the present invention, the heat treatment apparatus comprises: a chamber for receiving a substrate therein; a holder for holding the substrate in the chamber; an auxiliary light source provided on one side of the chamber and for irradiating the substrate held by the holder with light; and a flash lamp provided on the other side of the chamber and for irradiating the substrate preheated by the auxiliary light source with a flash of light, the auxiliary light source including a plurality of laser diodes.

The laser diodes emit relatively intense light with a wavelength shorter than 1 μm, and are capable of heating the substrate efficiently to a high temperature.

Preferably, the vertical cavity surface emitting lasers are arranged annularly around the optical element to irradiate a peripheral portion of the substrate with light.

This supplements the heating of the peripheral portion of the substrate where a temperature decrease occurs to provide a uniform in-plane temperature distribution of the substrate.

Preferably, the auxiliary light source includes vertical cavity surface emitting lasers for emitting light with different wavelengths and laser diodes for emitting light with different wavelengths.

This allows the uniform heating of the entire surface of the substrate to improve the in-plane uniformity of the temperature distribution even if a film with low absorptance for light with a specific wavelength is formed in part of the substrate.

It is therefore an object of the present invention to heat a substrate efficiently to a high temperature.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a longitudinal sectional view showing a configuration of a heat treatment apparatus according to a first preferred embodiment of the present invention;

FIG. 2 is a perspective view showing the entire external appearance of a holder;

FIG. 3 is a plan view of a susceptor;

FIG. 4 is a sectional view of the susceptor;

FIG. 5 is a plan view of a transfer mechanism;

FIG. 6 is a side view of the transfer mechanism;

FIG. 7 is a plan view showing an arrangement of an optical element and a plurality of VCSELs;

FIG. 8 is a schematic view showing light irradiation by means of the optical element and the plurality of VCSELs;

FIG. 9 is a graph showing a temperature distribution of a semiconductor wafer caused by light irradiation from laser diodes;

FIG. 10 is a view showing a configuration of the heat treatment apparatus according to a second preferred embodiment;

FIG. 11 is a plan view showing an example of the arrangement and configuration of the plurality of laser diodes and the plurality of VCSELs according to a third preferred embodiment;

FIG. 12 is a plan view showing an arrangement of the optical element and the plurality of VCSELs according to a fourth preferred embodiment;

FIG. 13 is a schematic view showing light irradiation from the optical element and the plurality of VCSELs according to the fourth preferred embodiment; and

FIG. 14 is a view showing a configuration of a light source for an auxiliary heating part according to a fifth preferred embodiment.

### DESCRIPTION OF THE PREFERRED EMBODIMENTS

Preferred embodiments according to the present invention will now be described in detail with reference to the drawings. In the following description, expressions indicating relative or absolute positional relationships (e.g., “in one direction”, “along one direction”, “parallel”, “orthogonal”, “center”, “concentric”, and “coaxial”) shall represent not only the exact positional relationships but also a state in which the angle or distance is relatively displaced to the extent that tolerances or similar functions are obtained, unless otherwise specified. Also, expressions indicating equal states (e.g., “identical”, “equal”, and “homogeneous”) shall represent not only a state of quantitatively exact equality but also a state in which there are differences that provide tolerances or similar functions, unless otherwise specified. Also, expressions indicating shapes (e.g., “circular”, “rectangular”, and “cylindrical”) shall represent not only the geometrically exact shapes but also shapes to the extent that the same level of effectiveness is obtained, unless otherwise specified, and may have unevenness or chamfers. Also, an expression such as “comprising”, “equipped with”, “provided with”, “including”, or “having” a component is not an exclusive expression that excludes the presence of other components. Also, the expression “at least one of A, B, and C” includes “A only”, “B only”, “C only”, “any two of A, B, and C”, and “all of A, B, and C”.

### First Preferred Embodiment

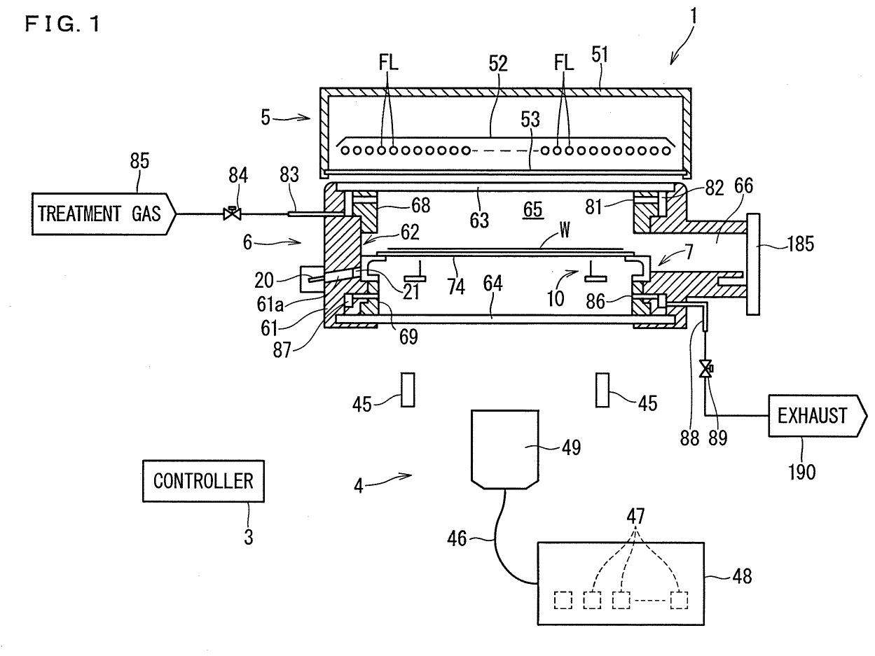

FIG. 1 is a longitudinal sectional view showing a configuration of a heat treatment apparatus 1 according to a first preferred embodiment of the present invention. The heat treatment apparatus 1 of FIG. 1 is a flash lamp annealer for irradiating a disk-shaped semiconductor wafer W serving as a substrate with flashes of light to heat the semiconductor wafer W. The size of the semiconductor wafer W to be treated is not particularly limited. For example, the semiconductor wafer W to be treated has a diameter of 300 mm and 450 mm. It should be noted that the dimensions of components and the number of components are shown in exaggeration or in simplified form, as appropriate, in FIG. 1 and the subsequent figures for the sake of easier understanding.

The heat treatment apparatus 1 includes a chamber 6 for receiving a semiconductor wafer W therein, a flash heating part 5 including a plurality of built-in flash lamps FL, and an auxiliary heating part 4 including a plurality of VCSELs (Vertical Cavity Surface Emitting Lasers) 45 and a plurality of laser diodes 47. The flash heating part 5 is provided over the chamber 6, and the auxiliary heating part 4 is provided under the chamber 6. The heat treatment apparatus 1 further includes a holder 7 provided inside the chamber 6 and for holding a semiconductor wafer W in a horizontal attitude, and a transfer mechanism 10 provided inside the chamber 6 and for transferring a semiconductor wafer W between the holder 7 and the outside of the heat treatment apparatus 1. The heat treatment apparatus 1 further includes a controller 3 for controlling operating mechanisms provided in the auxiliary heating part 4, the flash heating part 5, and the chamber 6 to cause the operating mechanisms to heat-treat a semiconductor wafer W.

The chamber 6 is configured such that upper and lower chamber windows 63 and 64 made of quartz are mounted to the top and bottom, respectively, of a tubular chamber side portion 61. The chamber side portion 61 has a generally tubular shape having an open top and an open bottom. The upper chamber window 63 is mounted to block the top opening of the chamber side portion 61, and the lower chamber window 64 is mounted to block the bottom opening thereof. The upper chamber window 63 forming the ceiling of the chamber 6 is a disk-shaped member made of quartz, and serves as a quartz window that transmits flashes of light emitted from the flash heating part 5 therethrough into the chamber 6. The lower chamber window 64 forming the floor of the chamber 6 is also a disk-shaped member made of quartz, and serves as a quartz window that transmits light emitted from the auxiliary heating part 4 therethrough into the chamber 6.

An upper reflective ring 68 is mounted to an upper portion of the inner wall surface of the chamber side portion 61, and a lower reflective ring 69 is mounted to a lower portion thereof. Both of the upper and lower reflective rings 68 and 69 are in the form of an annular ring. The upper reflective ring 68 is mounted by being inserted downwardly from the top of the chamber side portion 61. The lower reflective ring 69, on the other hand, is mounted by being inserted upwardly from the bottom of the chamber side portion 61 and fastened with screws not shown. In other words, the upper and lower reflective rings 68 and 69 are removably mounted to the chamber side portion 61. An interior space of the chamber 6, i.e. a space surrounded by the upper chamber window 63, the lower chamber window 64, the chamber side portion 61, and the upper and lower reflective rings 68 and 69, is defined as a heat treatment space 65.

A recessed portion 62 is defined in the inner wall surface of the chamber 6 by mounting the upper and lower reflective rings 68 and 69 to the chamber side portion 61. Specifically, the recessed portion 62 is defined which is surrounded by a middle portion of the inner wall surface of the chamber side portion 61 where the reflective rings 68 and 69 are not mounted, a lower end surface of the upper reflective ring 68, and an upper end surface of the lower reflective ring 69. The recessed portion 62 is provided in the form of a horizontal annular ring in the inner wall surface of the chamber 6, and surrounds the holder 7 which holds a semiconductor wafer W. The chamber side portion 61 and the upper and lower reflective rings 68 and 69 are made of a metal material (e.g., stainless steel) with high strength and high heat resistance.

The chamber side portion 61 is provided with a transport opening (throat) 66 for the transport of a semiconductor wafer W therethrough into and out of the chamber 6. The transport opening 66 is openable and closable by a gate valve 185. The transport opening 66 is connected in communication with an outer peripheral surface of the recessed portion 62. Thus, when the transport opening 66 is opened by the gate valve 185, a semiconductor wafer W is allowed to be transported through the transport opening 66 and the recessed portion 62 into and out of the heat treatment space 65. When the transport opening 66 is closed by the gate valve 185, the heat treatment space 65 in the chamber 6 is an enclosed space.

The chamber side portion 61 is further provided with a through hole 61a bored therein. A radiation thermometer 20 is mounted in a location of an outer wall surface of the chamber side portion 61 where the through hole 61a is provided. The through hole 61a is a cylindrical hole for directing infrared light emitted from a lower surface of a semiconductor wafer W held by a susceptor 74 to be described later therethrough to the radiation thermometer 20. The through hole 61a is inclined with respect to a horizontal direction so that a longitudinal axis (an axis extending in a direction in which the through hole 61a extends through the chamber side portion 61) of the through hole 61a intersects a main surface of the semiconductor wafer W held by the susceptor 74. Thus, the radiation thermometer 20 is provided obliquely below the susceptor 74. A transparent window 21 made of barium fluoride material transparent to infrared light in a wavelength range measurable by the radiation thermometer 20 is mounted to an end portion of the through hole 61a which faces the heat treatment space 65.

At least one gas supply opening 81 for supplying a treatment gas therethrough into the heat treatment space 65 is provided in an upper portion of the inner wall of the chamber 6. The gas supply opening 81 is provided above the recessed portion 62, and may be provided in the upper reflective ring 68. The gas supply opening 81 is connected in communication with a gas supply pipe 83 through a buffer space 82 provided in the form of an annular ring inside the side wall of the chamber 6. The gas supply pipe 83 is connected to a treatment gas supply source 85. A valve 84 is interposed in the gas supply pipe 83. When the valve 84 is opened, the treatment gas is fed from the treatment gas supply source 85 to the buffer space 82. The treatment gas flowing in the buffer space 82 flows in a spreading manner within the buffer space 82 which is lower in fluid resistance than the gas supply opening 81, and is supplied through the gas supply opening 81 into the heat treatment space 65. Examples of the treatment gas usable herein include inert gases such as nitrogen gas (N₂), reactive gases such as hydrogen (H₂) and ammonia (NH₃), and mixtures of these gases (although nitrogen gas is used in the present preferred embodiment).

At least one gas exhaust opening 86 for exhausting a gas from the heat treatment space 65 is provided in a lower portion of the inner wall of the chamber 6. The gas exhaust opening 86 is provided below the recessed portion 62, and may be provided in the lower reflective ring 69. The gas exhaust opening 86 is connected in communication with a gas exhaust pipe 88 through a buffer space 87 provided in the form of an annular ring inside the side wall of the chamber 6. The gas exhaust pipe 88 is connected to an exhaust part 190. A valve 89 is interposed in the gas exhaust pipe 88. When the valve 89 is opened, the gas in the heat treatment space 65 is exhausted through the gas exhaust opening 86 and the buffer space 87 to the gas exhaust pipe 88. The at least one gas supply opening 81 and the at least one gas exhaust opening 86 may include a plurality of gas supply openings 81 and a plurality of gas exhaust openings 86, respectively, arranged in a circumferential direction of the chamber 6, and may be in the form of slits. The treatment gas supply source 85 and the exhaust part 190 may be mechanisms provided in the heat treatment apparatus 1 or be utility systems in a factory in which the heat treatment apparatus 1 is installed.

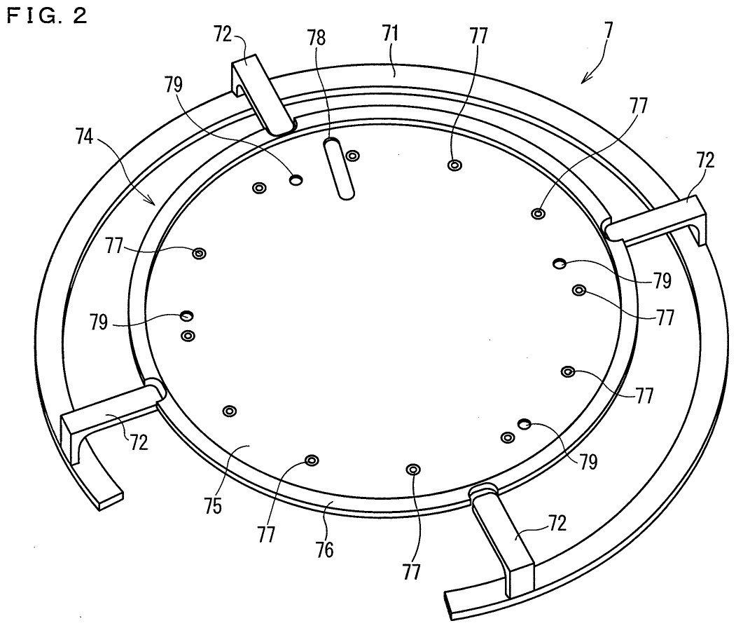

FIG. 2 is a perspective view showing the entire external appearance of the holder 7. The holder 7 includes a base ring 71, coupling portions 72, and the susceptor 74. The base ring 71, the coupling portions 72, and the susceptor 74 are all made of quartz. In other words, the whole of the holder 7 is made of quartz.

The base ring 71 is a quartz member having an arcuate shape obtained by removing a portion from an annular shape. This removed portion is provided to prevent interference between transfer arms 11 of the transfer mechanism 10 to be described later and the base ring 71. The base ring 71 is supported by the wall surface of the chamber 6 by being placed on the bottom surface of the recessed portion 62 (with reference to FIG. 1). The multiple coupling portions 72 (in the present preferred embodiment, four coupling portions 72) are mounted upright on the upper surface of the base ring 71 and arranged in a circumferential direction of the annular shape thereof. The coupling portions 72 are quartz members, and are rigidly secured to the base ring 71 by welding.

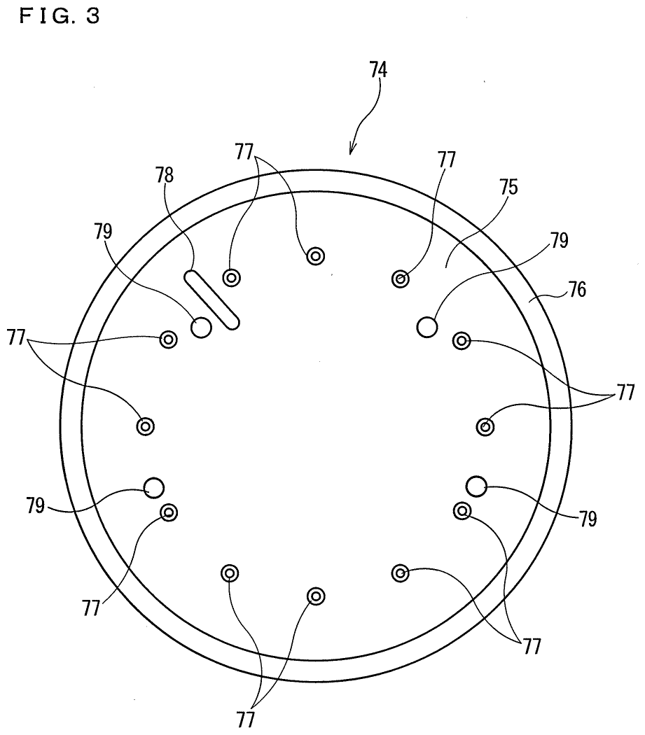

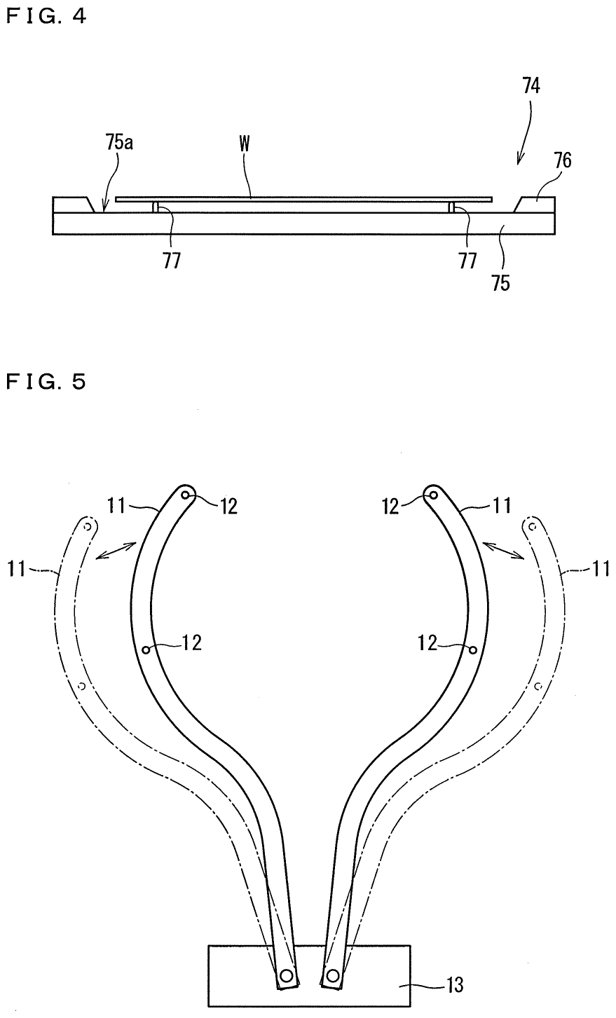

The susceptor 74 is supported by the four coupling portions 72 provided on the base ring 71. FIG. 3 is a plan view of the susceptor 74. FIG. 4 is a sectional view of the susceptor 74. The susceptor 74 includes a holding plate 75, a guide ring 76, and a plurality of substrate support pins 77. The holding plate 75 is a generally circular planar member made of quartz. The diameter of the holding plate 75 is greater than that of a semiconductor wafer W. In other words, the holding plate 75 has a size, as seen in plan view, greater than that of the semiconductor wafer W.

The guide ring 76 is provided on a peripheral portion of the upper surface of the holding plate 75. The guide ring 76 is an annular member having an inner diameter greater than the diameter of the semiconductor wafer W. For example, when the diameter of the semiconductor wafer W is 300 mm, the inner diameter of the guide ring 76 is 320 mm. The inner periphery of the guide ring 76 is in the form of a tapered surface which becomes wider in an upward direction from the holding plate 75. The guide ring 76 is made of quartz similar to that of the holding plate 75. The guide ring 76 may be welded to the upper surface of the holding plate 75 or fixed to the holding plate 75 with separately machined pins and the like. Alternatively, the holding plate 75 and the guide ring 76 may be machined as an integral member.

A region of the upper surface of the holding plate 75 which is inside the guide ring 76 serves as a planar holding surface 75a for holding the semiconductor wafer W. The substrate support pins 77 are provided upright on the holding surface 75a of the holding plate 75. In the present preferred embodiment, a total of 12 substrate support pins 77 are spaced at intervals of 30 degrees along the circumference of a circle concentric with the outer circumference of the holding surface 75a (the inner circumference of the guide ring 76). The diameter of the circle on which the 12 substrate support pins 77 are disposed (the distance between opposed ones of the substrate support pins 77) is smaller than the diameter of the semiconductor wafer W, and is 270 to 280 mm (in the present preferred embodiment, 270 mm) when the diameter of the semiconductor wafer W is 300 mm. Each of the substrate support pins 77 is made of quartz. The substrate support pins 77 may be provided by welding on the upper surface of the holding plate 75 or machined integrally with the holding plate 75.

Referring again to FIG. 2, the four coupling portions 72 provided upright on the base ring 71 and the peripheral portion of the holding plate 75 of the susceptor 74 are rigidly secured to each other by welding. In other words, the susceptor 74 and the base ring 71 are fixedly coupled to each other with the coupling portions 72. The base ring 71 of such a holder 7 is supported by the wall surface of the chamber 6, whereby the holder 7 is mounted to the chamber 6. With the holder 7 mounted to the chamber 6, the holding plate 75 of the susceptor 74 assumes a horizontal attitude (an attitude such that the normal to the holding plate 75 coincides with a vertical direction). In other words, the holding surface 75a of the holding plate 75 becomes a horizontal surface.

A semiconductor wafer W transported into the chamber 6 is placed and held in a horizontal attitude on the susceptor 74 of the holder 7 mounted to the chamber 6. At this time, the semiconductor wafer W is supported by the 12 substrate support pins 77 provided upright on the holding plate 75, and is held by the susceptor 74. More strictly speaking, the 12 substrate support pins 77 have respective upper end portions coming in contact with the lower surface of the semiconductor wafer W to support the semiconductor wafer W.

The semiconductor wafer W is supported in a horizontal attitude by the 12 substrate support pins 77 because the 12 substrate support pins 77 have a uniform height (distance from the upper ends of the substrate support pins 77 to the holding surface 75a of the holding plate 75).

The semiconductor wafer W supported by the substrate support pins 77 is spaced a predetermined distance apart from the holding surface 75a of the holding plate 75. The thickness of the guide ring 76 is greater than the height of the substrate support pins 77. Thus, the guide ring 76 prevents the horizontal misregistration of the semiconductor wafer W supported by the substrate support pins 77.

As shown in FIGS. 2 and 3, an opening 78 is provided in the holding plate 75 of the susceptor 74 so as to extend vertically through the holding plate 75 of the susceptor 74. The opening 78 is provided for the radiation thermometer 20 to receive radiation (infrared light) emitted from the lower surface of the semiconductor wafer W. Specifically, the radiation thermometer 20 receives the radiation emitted from the lower surface of the semiconductor wafer W through the opening 78 and the transparent window 21 mounted to the through hole 61a in the chamber side portion 61 to measure the temperature of the semiconductor wafer W. Further, the holding plate 75 of the susceptor 74 includes four through holes 79 bored therein and designed so that lift pins 12 of the transfer mechanism 10 to be described later pass through the through holes 79, respectively, to transfer a semiconductor wafer W.

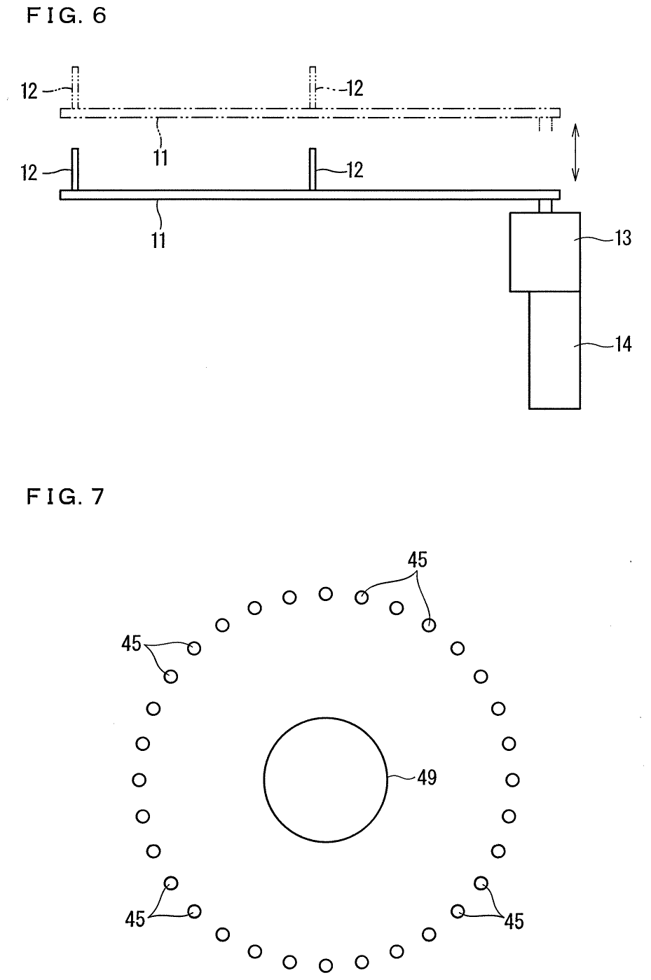

FIG. 5 is a plan view of the transfer mechanism 10. FIG. 6 is a side view of the transfer mechanism 10. The transfer mechanism 10 includes the two transfer arms 11. The transfer arms 11 are of an arcuate configuration extending substantially along the annular recessed portion 62. Each of the transfer arms 11 includes the two lift pins 12 mounted upright thereon. The transfer arms 11 and the lift pins 12 are made of quartz. The transfer arms 11 are pivotable by a horizontal movement mechanism 13. The horizontal movement mechanism 13 moves the pair of transfer arms 11 horizontally between a transfer operation position (a position indicated by solid lines in FIG. 5) in which a semiconductor wafer W is transferred to and from the holder 7 and a retracted position (a position indicated by dash-double-dot lines in FIG. 5) in which the transfer arms 11 do not overlap the semiconductor wafer W held by the holder 7 as seen in plan view. The horizontal movement mechanism 13 may be of the type which causes individual motors to pivot the transfer arms 11 respectively or of the type which uses a linkage mechanism to cause a single motor to pivot the pair of transfer arms 11 in cooperative relation.

The transfer arms 11 are moved upwardly and downwardly together with the horizontal movement mechanism 13 by an elevating mechanism 14. As the elevating mechanism 14 moves up the pair of transfer arms 11 in their transfer operation position, the four lift pins 12 in total pass through the respective four through holes 79 (with reference to FIGS. 2 and 3) bored in the susceptor 74, so that the upper ends of the lift pins 12 protrude from the upper surface of the susceptor 74. On the other hand, as the elevating mechanism 14 moves down the pair of transfer arms 11 in their transfer operation position to take the lift pins 12 out of the respective through holes 79 and the horizontal movement mechanism 13 moves the pair of transfer arms 11 so as to open the transfer arms 11, the transfer arms 11 move to their retracted position. The retracted position of the pair of transfer arms 11 is immediately over the base ring 71 of the holder 7. The retracted position of the transfer arms 11 is inside the recessed portion 62 because the base ring 71 is placed on the bottom surface of the recessed portion 62. An exhaust mechanism not shown is also provided near the location where the drivers (the horizontal movement mechanism 13 and the elevating mechanism 14) of the transfer mechanism 10 are provided, and is configured to exhaust an atmosphere around the drivers of the transfer mechanism 10 to the outside of the chamber 6.

Referring again to FIG. 1, the flash heating part 5 provided over the chamber 6 includes an enclosure 51, a light source provided inside the enclosure 51 and including the multiple (in the present preferred embodiment, 30) xenon flash lamps FL, and a reflector 52 provided inside the enclosure 51 so as to cover the light source from above. The flash heating part 5 further includes a lamp light radiation window 53 mounted to the bottom of the enclosure 51. The lamp light radiation window 53 forming the floor of the flash heating part 5 is a plate-like quartz window made of quartz. The flash heating part 5 is provided over the chamber 6, whereby the lamp light radiation window 53 is opposed to the upper chamber window 63. The flash lamps FL direct flashes of light from over the chamber 6 through the lamp light radiation window 53 and the upper chamber window 63 toward the heat treatment space 65.

The flash lamps FL, each of which is a rod-shaped lamp having an elongated cylindrical shape, are arranged in a plane so that the longitudinal directions of the respective flash lamps FL are in parallel with each other along a main surface of a semiconductor wafer W held by the holder 7 (that is, in a horizontal direction). Thus, a plane defined by the arrangement of the flash lamps FL is also a horizontal plane. A region in which the flash lamps FL are arranged has a size, as seen in plan view, greater than that of the semiconductor wafer W.

Each of the xenon flash lamps FL includes a cylindrical glass tube (discharge tube) containing xenon gas sealed therein and having positive and negative electrodes provided on opposite ends thereof and connected to a capacitor, and a trigger electrode attached to the outer peripheral surface of the glass tube. Because the xenon gas is electrically insulative, no current flows in the glass tube in a normal state even if electrical charge is stored in the capacitor. However, if a high voltage is applied to the trigger electrode to produce an electrical breakdown, electricity stored in the capacitor flows momentarily in the glass tube, and xenon atoms or molecules are excited at this time to cause light emission. Such a xenon flash lamp FL has the property of being capable of emitting extremely intense light as compared with a light source that stays lit continuously such as a halogen lamp because the electrostatic energy previously stored in the capacitor is converted into an ultrashort light pulse ranging from 0.1 to 100 milliseconds. Thus, the flash lamps FL are pulsed light emitting lamps which emit light instantaneously for an extremely short time period of less than one second. The light emission time of the flash lamps FL is adjustable by the coil constant of a lamp light source which supplies power to the flash lamps FL.

The reflector 52 is provided over the plurality of flash lamps FL so as to cover all of the flash lamps FL. A fundamental function of the reflector 52 is to reflect flashes of light emitted from the plurality of flash lamps FL toward the heat treatment space 65. The reflector 52 is a plate made of an aluminum alloy. A surface of the reflector 52 (a surface which faces the flash lamps FL) is roughened by abrasive blasting.

The auxiliary heating part 4 is provided on the opposite side of the chamber 6 from the flash heating part 5, i.e. under the chamber 6. The auxiliary heating part 4 includes a cabinet 48 incorporating the plurality of laser diodes 47, an optical element 49, and the plurality of VCSELs 45. The auxiliary heating part 4 is an auxiliary light source which heats the semiconductor wafer W by directing light from under the chamber 6 through the lower chamber window 64 toward the heat treatment space 65 by means of the plurality of laser diodes 47 and the plurality of VCSELs 45.

FIG. 7 is a plan view showing an arrangement of the optical element 49 and the plurality of VCSELs 45. The optical element 49 in the present preferred embodiment is a quartz member having a generally cylindrical shape, and is a DOE (Diffractive Optical Element) which uses the diffraction phenomenon of light. The optical element 49 is disposed under a central portion of the semiconductor wafer W held by the holder 7. On the other hand, the VCSELs 45 are arranged annularly around the optical element 49. The number of annularly arranged VCSELs 45 may be any appropriate number. The VCSELs 45 are disposed under a peripheral portion of the semiconductor wafer W held by the holder 7.

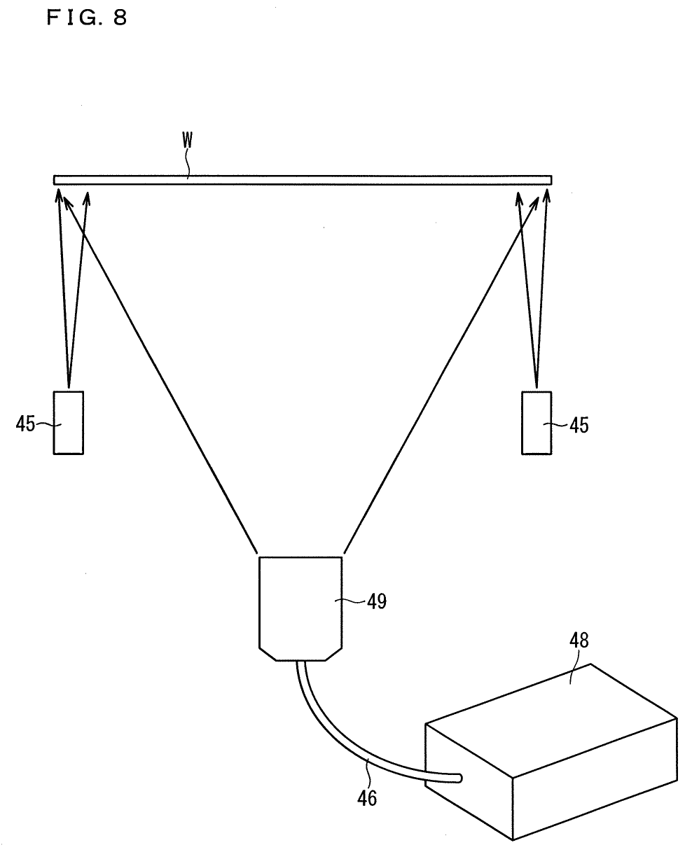

FIG. 8 is a schematic view showing light irradiation by means of the optical element 49 and the plurality of VCSELs 45. The optical element 49 has a lower end surface connected through an optical fiber 46 to the cabinet 48. The laser diodes 47 are provided in the cabinet 48 (FIG. 1). Each of the laser diodes 47 is an element which causes laser oscillation by passing current through a semiconductor, and is referred to also as a semiconductor laser. The laser diodes 47 have high output conversion efficiency and are capable of emitting light with a higher intensity than LEDs, as well as have a long life. Beams of laser light emitted from the laser diodes 47 are gathered and combined in the cabinet 48, and guided to the optical element 49 by the optical fiber 46.

In general, laser light is highly directional, and the laser light emitted from the laser diodes 47 and entering the optical element 49 has the property of traveling straight forward while hardly diverging. The optical element 49 is a diffractive optical element which diffracts incident light by micromachining a quartz member to thereby output light in various patterns. The optical element 49 spatially branches off the laser light guided by the optical fiber 46 and entering the lower end surface thereof, and emits the light diverging from an upper end surface thereof. In other words, the highly directional laser light guided from the cabinet 48 by the optical fiber 46 is diffracted by the optical element 49 to become light travelling in a divergent manner. Thus, the light emitted from the upper end surface of the optical element 49 is applied to the entire lower surface of the semiconductor wafer W held by the holder 7.

The intensity distribution of the laser light emitted from the laser diodes 47 and guided by the optical fiber 46 is close to a Gaussian distribution. Specifically, the intensity of the laser light is the highest near the center of the optical axis thereof and decreases as the distance from the optical axis increases. The optical element 49 also has the function of making the intensity distribution of the incident light uniform. Thus, the intensity distribution of the laser light entering the optical element 49 is made uniform, so that light with a uniform illuminance distribution from the optical element 49 is applied to the lower surface of the semiconductor wafer W.

On the other hand, each of the VCSELs (Vertical Cavity Surface Emitting Lasers) 45 is a type of semiconductor laser, and emits light in a direction perpendicular to the surface of the semiconductor substrate. The VCSELs 45 are capable of emitting light with a relatively high intensity, and emit highly directional light. In other words, the irradiation area of the VCSELs 45 is small. The VCSELs 45 are disposed under the peripheral portion of the semiconductor wafer W held by the holder 7, and light is emitted vertically upwardly from each of the VCSELs 45. Thus, only the peripheral portion of the semiconductor wafer W is irradiated in a limited manner with light from the VCSELs 45, whereas the entire lower surface of the semiconductor wafer W is irradiated with light from the optical element 49.

In the present preferred embodiment, the laser diodes 47 emit light with a wavelength of 960 to 985 nm. The VCSELs 45 emit light with a wavelength of 930 to 940 nm. Both the laser diodes 47 and the VCSELs 45 are continuous lighting lamps that emit light continuously for not less than one second.

The controller 3 controls the aforementioned various operating mechanisms provided in the heat treatment apparatus 1. The controller 3 is similar in hardware configuration to a typical computer. Specifically, the controller 3 includes a CPU that is a circuit for performing various computation processes, a ROM or read-only memory for storing a basic program therein, a RAM or readable/writable memory for storing various pieces of information therein, and a magnetic disk for storing control software, data and the like thereon. The CPU in the controller 3 executes a predetermined processing program, whereby the processes in the heat treatment apparatus 1 proceed.

The heat treatment apparatus 1 further includes, in addition to the aforementioned components, various cooling structures to prevent an excessive temperature rise in the auxiliary heating part 4, the flash heating part 5, and the chamber 6 because of the heat energy generated from the laser diodes 47, the VCSELs 45, and the flash lamps FL during the heat treatment of a semiconductor wafer W. As an example, a water cooling tube (not shown) is provided in the walls of the chamber 6. Also, the auxiliary heating part 4 and the flash heating part 5 have an air cooling structure for forming a gas flow therein to exhaust heat. Air is supplied to a gap between the upper chamber window 63 and the lamp light radiation window 53 to cool down the flash heating part 5 and the upper chamber window 63.

Next, a treatment operation in the heat treatment apparatus 1 will be described. A typical heat treatment operation for an ordinary semiconductor wafer (product wafer) W that becomes a product will be described. The semiconductor wafer W to be treated is a semiconductor substrate of silicon (Si) implanted with impurities by ion implantation in a preceding step. The activation of the impurities is performed by an annealing process in the heat treatment apparatus 1. A procedure for the treatment of the semiconductor wafer W which will be described below proceeds under the control of the controller 3 over the operating mechanisms of the heat treatment apparatus 1.

Prior to the treatment of the semiconductor wafer W, the valve 84 for supply of gas is opened, and the valve 89 for exhaust of gas is opened, so that the supply and exhaust of gas into and out of the chamber 6 start. When the valve 84 is opened, nitrogen gas is supplied through the gas supply opening 81 into the heat treatment space 65. When the valve 89 is opened, the gas within the chamber 6 is exhausted through the gas exhaust opening 86. This causes the nitrogen gas supplied from an upper portion of the heat treatment space 65 in the chamber 6 to flow downwardly and then to be exhausted from a lower portion of the heat treatment space 65.

Subsequently, the gate valve 185 is opened to open the transport opening 66. A transport robot outside the heat treatment apparatus 1 transports a semiconductor wafer W to be treated through the transport opening 66 into the heat treatment space 65 of the chamber 6. At this time, there is a danger that an atmosphere outside the heat treatment apparatus 1 is carried into the heat treatment space 65 as the semiconductor wafer W is transported into the heat treatment space 65. However, the nitrogen gas is continuously supplied into the chamber 6. Thus, the nitrogen gas flows outwardly through the transport opening 66 to minimize the outside atmosphere carried into the heat treatment space 65.

The semiconductor wafer W transported into the heat treatment space 65 by the transport robot is moved forward to a position lying immediately over the holder 7 and is stopped thereat. Then, the pair of transfer arms 11 of the transfer mechanism 10 is moved horizontally from the retracted position to the transfer operation position and is then moved upwardly, whereby the lift pins 12 pass through the through holes 79 and protrude from the upper surface of the holding plate 75 of the susceptor 74 to receive the semiconductor wafer W. At this time, the lift pins 12 move upwardly to above the upper ends of the substrate support pins 77.

After the semiconductor wafer W is placed on the lift pins 12, the transport robot moves out of the heat treatment space 65, and the gate valve 185 closes the transport opening 66. Then, the pair of transfer arms 11 moves downwardly to transfer the semiconductor wafer W from the transfer mechanism 10 to the susceptor 74 of the holder 7, so that the semiconductor wafer W is held in a horizontal attitude from below. The semiconductor wafer W is supported by the substrate support pins 77 provided upright on the holding plate 75, and is held by the susceptor 74. The semiconductor wafer W is held by the holder 7 in such an attitude that the front surface thereof that is patterned and implanted with impurities is the upper surface. A predetermined distance is defined between a back surface (a main surface opposite from the front surface) of the semiconductor wafer W supported by the substrate support pins 77 and the holding surface 75a of the holding plate 75. The pair of transfer arms 11 moved downwardly below the susceptor 74 is moved back to the retracted position, i.e. to the inside of the recessed portion 62, by the horizontal movement mechanism 13.

After the semiconductor wafer W is held from below in a horizontal attitude by the susceptor 74 of the holder 7 made of quartz, the semiconductor wafer W is irradiated with light from the auxiliary heating part 4, so that preheating (or assist-heating) starts. The beams of laser light emitted from the laser diodes 47 are gathered and combined in the cabinet 48, and guided to the lower end surface of the optical element 49 by the optical fiber 46. The optical element 49 diffracts the laser light entering the lower end surface thereof to make the intensity distribution of the laser light uniform and to widen the direction of travel of the laser light, and then emits the laser light from the upper end surface thereof. The light emitted from the optical element 49 is transmitted through the lower chamber window 64 and the susceptor 74 both made of quartz, and applied with a uniform illuminance distribution to the entire lower surface of the semiconductor wafer W.

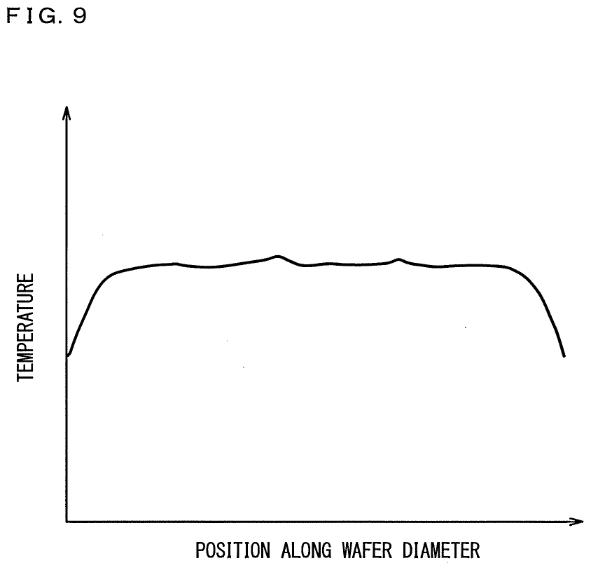

Even if light from the laser diodes 47 is applied with a uniform illuminance distribution to the entire lower surface of the semiconductor wafer W, the semiconductor wafer W has a non-uniform temperature distribution as shown in FIG. 9. Specifically, a temperature distribution occurs such that the temperature of the peripheral portion of the semiconductor wafer W is relatively lower than that of the central portion thereof. The reason why the temperature distribution is non-uniform in spite of the application of light with a uniform illuminance distribution is that a larger amount of heat is liable to be dissipated outwardly to cause a temperature decrease in the peripheral portion of the semiconductor wafer W than in the central portion thereof.

For this reason, the VCSELs 45 are provided in the first preferred embodiment so that the peripheral portion of the semiconductor wafer W is irradiated with light from the VCSELs 45. The VCSELs 45 irradiate the peripheral portion of the semiconductor wafer W with relatively intense and highly directional light. Thus, the light from the VCSELs 45 is applied to only the peripheral portion of the semiconductor wafer W where a relative temperature decrease occurs. This eliminates the temperature decrease in the peripheral portion of the semiconductor wafer W to provide a uniform temperature distribution over the entire surface of the semiconductor wafer W.

By receiving light irradiation from the laser diodes 47 and the VCSELs 45, the semiconductor wafer W is preheated, so that the temperature of the semiconductor wafer W increases. The temperature of the semiconductor wafer W which is on the increase by the irradiation with light from the auxiliary heating part 4 is measured by the radiation thermometer 20. The measured temperature of the semiconductor wafer W is transmitted to the controller 3. The controller 3 controls the outputs from the laser diodes 47 and the VCSELs 45 while monitoring whether the temperature of the semiconductor wafer W which is on the increase by the irradiation with light from the auxiliary heating part 4 reaches a predetermined preheating temperature T1 or not. In other words, the controller 3 effects feedback control of the outputs from the laser diodes 47 and the VCSELs 45 so that the temperature of the semiconductor wafer W is equal to the preheating temperature T1, based on the value measured by the radiation thermometer 20. The preheating temperature T1 shall be on the order of 200° to 800° C., preferably on the order of 350° to 600° C., (in the present preferred embodiment, 600° C.) at which there is no apprehension that the impurities implanted in the semiconductor wafer W are diffused by heat.

After the temperature of the semiconductor wafer W reaches the preheating temperature T1, the controller 3 maintains the temperature of the semiconductor wafer W at the preheating temperature T1 for a short time. Specifically, at the point in time when the temperature of the semiconductor wafer W measured by the radiation thermometer 20 reaches the preheating temperature T1, the controller 3 adjusts the outputs from the laser diodes 47 and the VCSELs 45 to maintain the temperature of the semiconductor wafer W at approximately the preheating temperature T1.

The flash lamps FL in the flash heating part 5 irradiate the front surface of the semiconductor wafer W held by the susceptor 74 with a flash of light at the point in time when a predetermined time period has elapsed since the temperature of the semiconductor wafer W reached the preheating temperature T1. At this time, part of the flash of light emitted from the flash lamps FL travels directly toward the interior of the chamber 6. The remainder of the flash of light is reflected once from the reflector 52, and then travels toward the interior of the chamber 6. The irradiation of the semiconductor wafer W with such flashes of light achieves the flash heating of the semiconductor wafer W.

The flash heating, which is achieved by the emission of a flash of light from the flash lamps FL, is capable of increasing the front surface temperature of the semiconductor wafer W in a short time. Specifically, the flash of light emitted from the flash lamps FL is an intense flash of light emitted for an extremely short period of time ranging from about 0.1 to about 100 milliseconds as a result of the conversion of the electrostatic energy previously stored in the capacitor into such an ultrashort light pulse. The front surface temperature of the semiconductor wafer W subjected to the flash heating by the flash irradiation from the flash lamps FL momentarily increases to a treatment temperature T2 of 1000° C. or higher. After the impurities implanted in the semiconductor wafer W are activated, the temperature of the front surface of the semiconductor wafer W decreases rapidly. Because of the capability of increasing and decreasing the temperature of the front surface of the semiconductor wafer W in an extremely short time, the heat treatment apparatus 1 achieves the activation of the impurities implanted in the semiconductor wafer W while suppressing the diffusion of the impurities due to heat. It should be noted that the time required for the activation of the impurities is extremely short as compared with the time required for the thermal diffusion of the impurities. Thus, the activation is completed in a short time ranging from about 0.1 to about 100 milliseconds during which no diffusion occurs.

After a predetermined time period has elapsed since the completion of the flash heating treatment, the irradiation with the light from the auxiliary heating part 4 also stops. This causes the temperature of the semiconductor wafer W to decrease rapidly from the preheating temperature T1. The radiation thermometer 20 measures the temperature of the semiconductor wafer W which is on the decrease. The result of measurement is transmitted to the controller 3. The controller 3 monitors whether the temperature of the semiconductor wafer W is decreased to a predetermined temperature or not, based on the result of measurement by means of the radiation thermometer 20. After the temperature of the semiconductor wafer W is decreased to the predetermined temperature or below, the pair of transfer arms 11 of the transfer mechanism 10 is moved horizontally again from the retracted position to the transfer operation position and is then moved upwardly, so that the lift pins 12 protrude from the upper surface of the susceptor 74 to receive the heat-treated semiconductor wafer W from the susceptor 74. Subsequently, the transport opening 66 which has been closed is opened by the gate valve 185, and the transport robot outside the heat treatment apparatus 1 transports the semiconductor wafer W placed on the lift pins 12 out of the chamber 6. Thus, the heating treatment of the semiconductor wafer W is completed.

During the preheating of the semiconductor wafer W in the first preferred embodiment, the laser diodes 47 are used to irradiate the entire surface of the semiconductor wafer W with light with a uniform illuminance distribution while the VCSELs 45 are used to irradiate the peripheral portion of the semiconductor wafer W with light. The laser diodes 47 apply light with a wavelength shorter than 1 μm to the semiconductor wafer W. The semiconductor wafer W of silicon has a low spectral absorptance of infrared light with a wavelength exceeding 1 μm in a low temperature range of 500° C. or below, but has a relatively high spectral absorptance of light with a wavelength of not greater than 1 μm. In other words, the semiconductor wafer W excellently absorbs light emitted from the laser diodes 47 even in a low temperature range of 500° C. or below. Thus, the laser diodes 47 efficiently heat the semiconductor wafer W even when the temperature of the semiconductor wafer W is 500° C. or below in the initial stage of the preheating.

The laser diodes 47 also emit light with a higher intensity than LEDs. Thus, the temperature of the semiconductor wafer W is increased to the desired preheating temperature T1 by the laser diodes 47. That is, the light irradiation from the laser diodes 47 efficiently heats the semiconductor wafer W to a high temperature.

However, even when light with a uniform illuminance distribution is applied from the laser diodes 47 to the entire lower surface of the semiconductor wafer W, there arises a non-uniform temperature distribution such that the temperature of the peripheral portion of the semiconductor wafer W which is liable to cool is lower than that of the central portion thereof. To prevent this, the annularly arranged VCSELs 45 disposed under the peripheral portion of the semiconductor wafer W are used to irradiate the peripheral portion with highly directional light. The VCSELs 45, which are also capable of emitting light with a relatively high intensity, supplement the heating of the peripheral portion of the semiconductor wafer W where the temperature decrease occurs to provide a uniform in-plane temperature distribution of the semiconductor wafer W.

### Second Preferred Embodiment

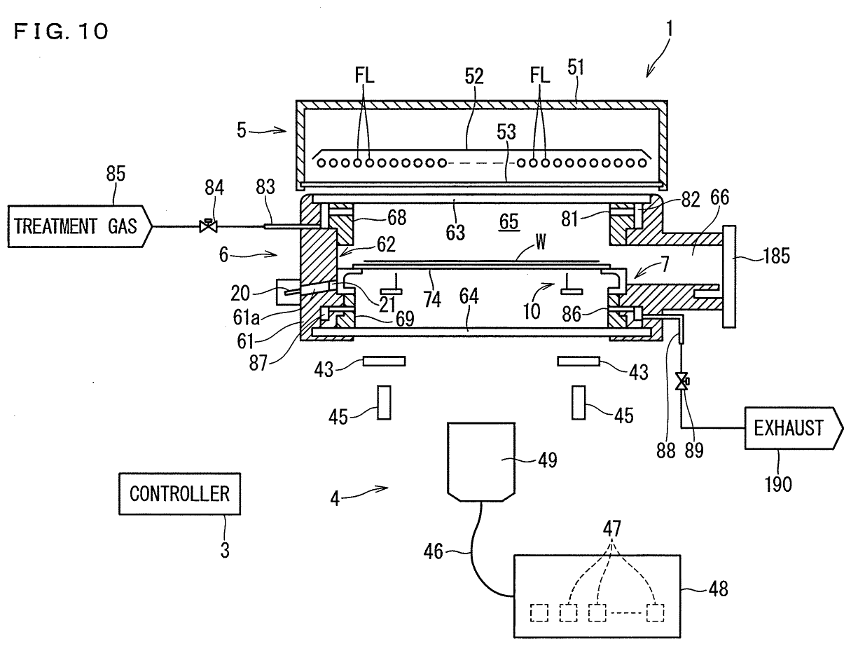

Next, a second preferred embodiment of the present invention will be described. FIG. 10 is a view showing a configuration of the heat treatment apparatus according to the second preferred embodiment. A plurality of homogenizers 43 for making the distribution of light emitted from the respective VCSELs 45 uniform are provided in the second preferred embodiment.

The homogenizers 43 are quartz members provided between the VCSELs 45 and the lower chamber window 64 of the chamber 6. The homogenizers 43 are also diffractive optical elements which make the intensity distribution of light emitted from the corresponding VCSELs 45 uniform.

The intensity distribution of light emitted from the VCSELs 45 is close to a Gaussian distribution because each of the VCSELs 45 is a type of semiconductor laser which emits relatively highly directional light. For this reason, when light from the VCSELs 45 is directly applied to the semiconductor wafer W, there is appreciation that regions of high illuminance and other regions appear locally on the irradiated surface of the semiconductor wafer W, resulting in unevenness in illuminance. The homogenizers 43 make the intensity distribution of light emitted from the VCSELs 45 uniform to eliminate the unevenness in illuminance on the irradiated surface of the semiconductor wafer W, thereby providing a uniform illuminance distribution. As a result, this provides a more uniform in-plane temperature distribution of the semiconductor wafer W during the preheating.

The configuration of the heat treatment apparatus of the second preferred embodiment is the same as that of the heat treatment apparatus 1 of the first preferred embodiment except that the homogenizers 43 are provided. The procedure for the treatment of the semiconductor wafer W in the heat treatment apparatus of the second preferred embodiment is also the same as that in the heat treatment apparatus 1 of the first preferred embodiment.

### Third Preferred Embodiment

Next, a third preferred embodiment of the present invention will be described. In the third preferred embodiment, the optical element 49 is not provided, and light from the laser diodes 47 is directly applied to the semiconductor wafer W.

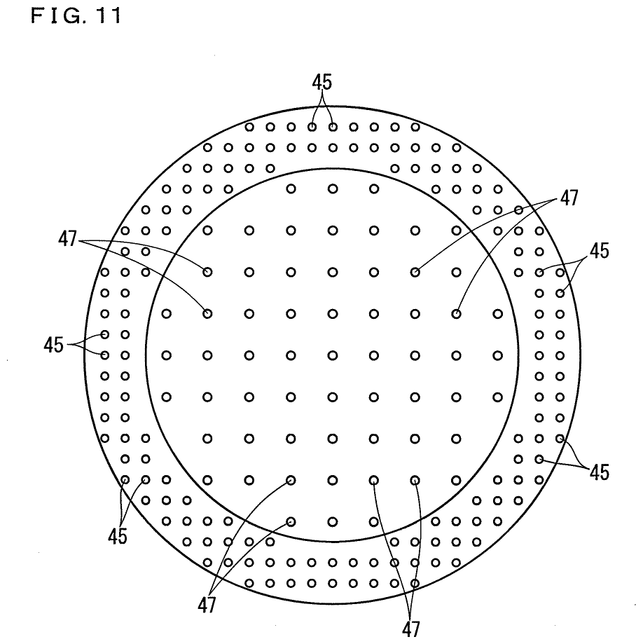

FIG. 11 is a plan view showing an example of the arrangement and configuration of the plurality of laser diodes 47 and the plurality of VCSELs 45 according to the third preferred embodiment. The laser diodes 47 are arranged in a plane at a uniform density in a circular region lying under the central portion of the semiconductor wafer W held by the holder 7. The VCSELs 45 are arranged at a uniform density in an annular region surrounding the circular region in which the laser diodes 47 are arranged. The annular region in which the VCSELs 45 are arranged lies under the peripheral portion of the semiconductor wafer W. In other words, the laser diodes 47 are arranged in a central portion of the auxiliary heating part 4 of the third preferred embodiment, and the VCSELs 45 are arranged in a peripheral portion thereof.

Although the laser diodes 47 emit highly directional laser light, the entire lower surface of the semiconductor wafer W is irradiated with light by arranging the laser diodes 47 at the uniform density in the circular region as shown in FIG. 11. However, even when the laser diodes 47 are arranged at the uniform density in the circular region, there arises a non-uniform temperature distribution such that the temperature of the peripheral portion of the semiconductor wafer W is lower than that of the central portion thereof as in the first preferred embodiment. To prevent this, the VCSELs 45 are provided so as to face the peripheral portion of the semiconductor wafer W and apply light to the peripheral portion of the semiconductor wafer W. This strongly heats the peripheral portion of the semiconductor wafer W where the temperature is liable to lower to eliminate the temperature decrease in the peripheral portion, thereby providing a uniform in-plane temperature distribution of the semiconductor wafer W.

The remaining configuration of the third preferred embodiment is the same as that of first preferred embodiment. The procedure for the treatment of the semiconductor wafer W in the third preferred embodiment is also the same as that in the first preferred embodiment.

### Fourth Preferred Embodiment

Next, a fourth preferred embodiment of the present invention will be described. In the fourth preferred embodiment, additional VCSELs 45 are provided in addition to the VCSELs 45 of the first preferred embodiment.

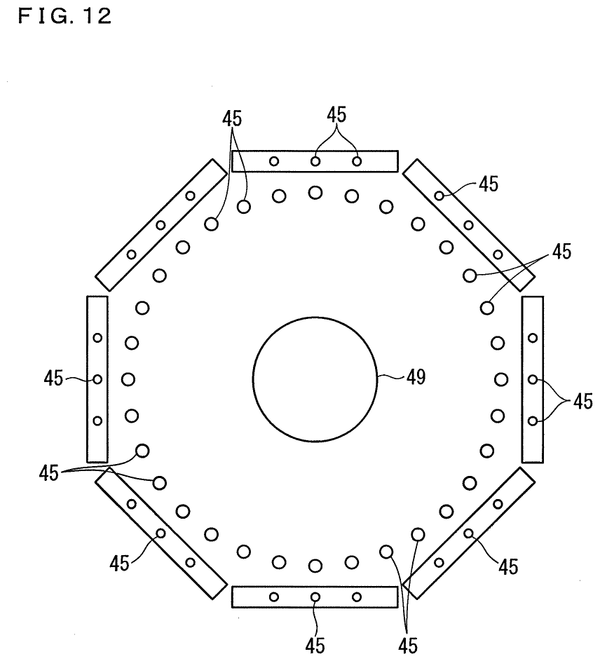

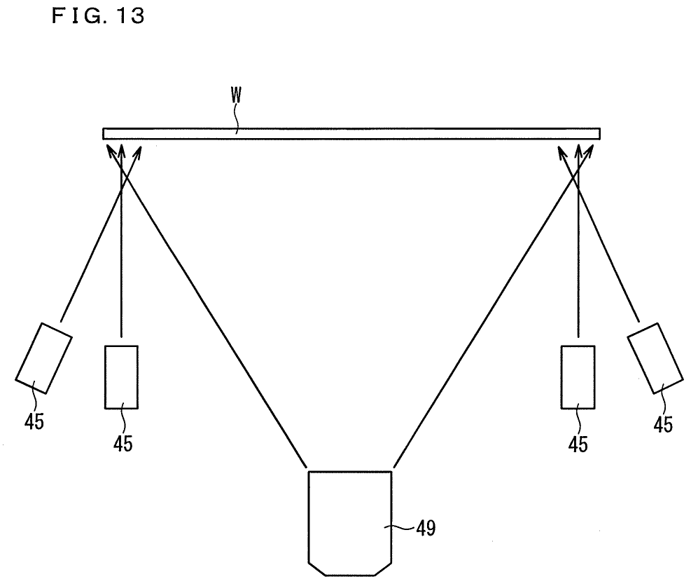

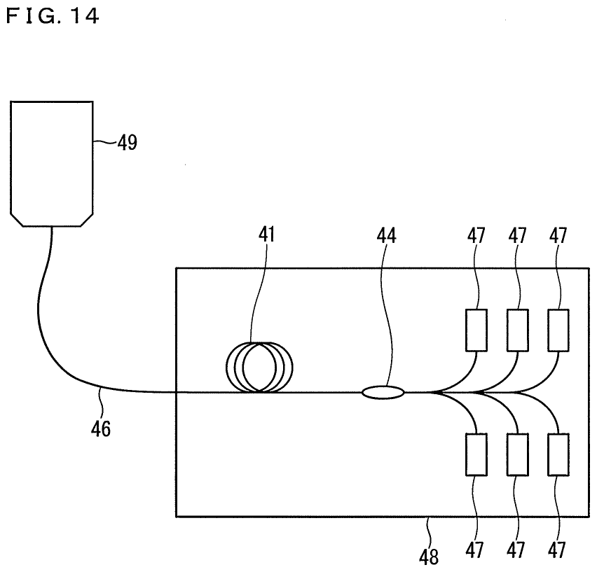

FIG. 12 is a plan view showing an arrangement of the optical element 49 and the plurality of VCSELs 45 according to the fourth preferred embodiment. FIG. 13 is a schematic view showing light irradiation from the optical element 49 and the plurality of VCSELs 45 according to the fourth preferred embodiment. In the fourth preferred embodiment, the additional VCSELs 45 are arranged around the annularly arranged VCSELs 45 of the first preferred embodiment. The additional VCSELs 45 are provided in an inclined attitude in a region outside the semiconductor wafer W held by the holder 7.

More specifically, the VCSELs 45 are arranged annularly under the peripheral portion of the semiconductor wafer W held by the holder 7 as in the first preferred embodiment. The additional VCSELs 45 are further arranged in the region around the annularly arranged VCSELs 45 and outside the semiconductor wafer W. The additional VCSELs 45 in the region outside the semiconductor wafer W are arranged in an inclined attitude so that their irradiation direction is toward the lower surface of the semiconductor wafer W. The configuration and the procedure for the treatment of the semiconductor wafer W in the fourth preferred embodiment are the same as those in the first preferred embodiment except that the additional VCSELs 45 are provided.

In the fourth preferred embodiment, as in the first preferred embodiment, the laser diodes 47 are used to irradiate the entire surface of the semiconductor wafer W with light with a uniform illuminance distribution while the annularly arranged VCSELs 45 are used to irradiate the peripheral portion of the semiconductor wafer W with light. This applies highly directional light from the VCSELs 45 to the peripheral portion of the semiconductor wafer W where the temperature is liable to lower to strongly heat the peripheral portion, thereby providing a uniform in-plane temperature distribution of the semiconductor wafer W. In the fourth preferred embodiment, the additional light irradiation from the additional VCSELs 45 is further performed in the plane of the semiconductor wafer W, whereby the semiconductor wafer W is heated more efficiently to a high temperature.

### Fifth Preferred Embodiment

Next, a fifth preferred embodiment of the present invention will be described. In the fifth preferred embodiment, a fiber laser is used which amplifies laser light emitted from the laser diodes 47 through the use of an optical fiber doped with a rare-earth element.

FIG. 14 is a view showing a configuration of a light source for the auxiliary heating part according to the fifth preferred embodiment. Like reference numerals are used in FIG. 14 to designate components identical with those of the first preferred embodiment. The plurality of laser diodes 47, a pump combiner 44, and a rare-earth doped fiber 41 are provided in the cabinet 48. The rare-earth doped fiber 41 is an optical fiber with a core doped with a rare-earth element. Examples of the rare-earth element for doping include ytterbium (Yb), neodymium (Nd), thulium (Tm), and erbium (Er). The rare-earth doped fiber 41 further includes two layers of cladding outside the core. Both ends of the rare-earth doped fiber 41 are provided with mirrors or fiber bragg gratings (FBGs) not shown.

Beams of laser light emitted from the laser diodes 47 are combined by the pump combiner 44. The combined laser light enters the rare-earth doped fiber 41 as excitation light. The excitation light excites the doped rare-earth element, whereby laser light is emitted. In other words, the laser light is amplified. The emitted laser light is guided to the optical element 49 by the optical fiber 46. Then, the light emitted from the upper end surface of the optical element 49 is applied to the lower surface of the semiconductor wafer W, as in the first preferred embodiment. The fiber laser as in the fifth preferred embodiment provides good amplification efficiency of laser light because excitation and emission are performed in the thin core in the rare-earth doped fiber 41.

### Modifications

While the preferred embodiments according to the present invention have been described hereinabove, various modifications of the present invention in addition to those described above may be made without departing from the scope and spirit of the invention. For example, the laser diodes 47 and the VCSELs 45 are provided in the auxiliary heating part 4 in the aforementioned preferred embodiments. However, only the laser diodes 47 may be instead provided in the auxiliary heating part 4. In this case, the semiconductor wafer W is preheated by only the laser diodes 47. The laser diodes 47 apply light with a wavelength shorter than 1 μm to the semiconductor wafer W. Thus, the light is excellently absorbed even by the semiconductor wafer W which is relatively low in temperature in the initial stage of the preheating. Also, the laser diodes 47 emit light with a relatively high intensity. That is, the laser diodes 47 are capable of heating the semiconductor wafer W more efficiently to a higher temperature than conventional halogen lamps.

When only the laser diodes 47 are provided in the auxiliary heating part 4 without the VCSELs 45, the optical element 49 may be provided as in the first preferred embodiment or the laser diodes 47 may be arranged in a plane as in the third preferred embodiment. When the optical element 49 is provided, it is preferable to diffract the incident light so that the intensity distribution is such that relatively intense light is applied to the peripheral portion of the semiconductor wafer W. This provides a uniform in-plane temperature distribution of the semiconductor wafer W.

In the aforementioned preferred embodiments, a single wavelength is used as the wavelength of light emitted from the laser diodes 47 and the VCSELs 45. However, at least either the laser diodes 47 or the VCSELs 45 may emit light with a plurality of different wavelengths. In other words, the laser diodes 47 which emit light with different wavelengths and/or the VCSELs 45 which emit light with different wavelengths may be provided in the auxiliary heating part 4. When light with a single wavelength is emitted from the laser diodes 47 and the VCSELs 45, there is apprehension that the temperature of only part of the semiconductor wafer W is relatively low so that the in-plane uniformity of the temperature distribution is impaired if the part of the semiconductor wafer W has a film with low absorptance for the light with the single wavelength. The emission of light with a plurality of wavelengths from the laser diodes 47 and/or the VCSELs 45 allows the uniform heating of the entire surface of the semiconductor wafer W to improve the in-plane uniformity of the temperature distribution even if a film with low absorptance for light with a specific wavelength is formed in part of the semiconductor wafer W.

The optical element 49 is not limited to the diffractive optical element, but may be an element which adjusts the optical path by refraction, for example.

Also, light guided by the optical fiber 46 may be directly applied to the semiconductor wafer W without providing the optical element 49.

In the aforementioned preferred embodiments, the auxiliary heating part 4 is provided under the chamber 6. The present invention, however, is not limited to this. The auxiliary heating part 4 including the laser diodes 47 and the VCSELs 45 may be provided over the chamber 6. In this case, the laser diodes 47 and the VCSELs 45 irradiate the semiconductor wafer W with light from above the chamber 6 to preheat the semiconductor wafer W.

In the aforementioned preferred embodiments, the VCSELs 45 are disposed so as to face the peripheral portion of the semiconductor wafer W. The present invention, however, is not limited to this. The VCSELs 45 may be provided so as to face part of the semiconductor wafer W where the temperature decrease is liable to occur during the preheating.

Although the 30 flash lamps FL are provided in the flash heating part 5 in the aforementioned preferred embodiments, the present invention is not limited to this. Any number of flash lamps FL may be provided. The flash lamps FL are not limited to the xenon flash lamps, but may be krypton flash lamps.

While the invention has been shown and described in detail, the foregoing description is in all aspects illustrative and not restrictive. It is therefore understood that numerous modifications and variations can be devised without departing from the scope of the invention.

What is claimed is:

1. A heat treatment apparatus for irradiating a substrate with light to heat the substrate, comprising:
a chamber for receiving a substrate therein;
a holder for holding said substrate in said chamber;
an auxiliary light source provided on one side of said chamber and for irradiating said substrate held by said holder with light; and
a flash lamp provided on the other side of said chamber and for irradiating said substrate preheated by said auxiliary light source with a flash of light,
said auxiliary light source including a plurality of laser diodes.

2. The heat treatment apparatus according to claim 1, further comprising
an optical element for guiding light emitted from said laser diodes so that the entire surface of said substrate is irradiated with the light with a uniform illuminance distribution.

3. The heat treatment apparatus according to claim 2,
wherein said auxiliary light source further includes a plurality of vertical cavity surface emitting lasers.

4. The heat treatment apparatus according to claim 3, further comprising
a plurality of homogenizers for making light emitted from the respective vertical cavity surface emitting lasers uniform.

5. The heat treatment apparatus according to claim 3,
wherein said vertical cavity surface emitting lasers are arranged annularly around said optical element to irradiate a peripheral portion of said substrate with light.

6. The heat treatment apparatus according to claim 5,
wherein said auxiliary light source further includes a plurality of additional vertical cavity surface emitting lasers around said annularly arranged vertical cavity surface emitting lasers, and said additional vertical cavity surface emitting lasers are provided in an inclined attitude so that their irradiation direction is toward said substrate.

7. The heat treatment apparatus according to claim 3,
wherein said auxiliary light source includes vertical cavity surface emitting lasers for emitting light with different wavelengths and laser diodes for emitting light with different wavelengths.
